(19) United States
(12) Patent Application Publication
(10) Pub. No.: US 2006/0016395 A1
(43) Pub. Date: Jan. 26, 2006

(54) Plasma processing apparatus

(75) Inventor: Yuu Nishimura, Moriya-Shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/169,631

(22) Filed: Jun. 30, 2005

(30) Foreign Application Priority Data
Jun. 30, 2004 (JP) 194234-2004(PAT.)

(51) Int. Cl. C23C 16/00

(52) U.S. Cl. 118/715

(57) ABSTRACT

Disclosed is a plasma processing apparatus including a plasma producing chamber into which a microwave and a plasma producing gas are to be introduced, a processing chamber being able to be communicated with the plasma producing chamber, a wafer table provided inside the processing chamber, for carrying thereon a wafer to be processed, and a partition plate provided at an interface between the plasma producing chamber and the processing chamber, and having openings for connecting the plasma producing chamber and the processing chamber for communication therebetween. The partition plate includes rectifying plates being provided at the openings with predetermined different tilt angles, and a reaction gas discharging nozzle for discharging a reaction gas into the processing chamber.

### FIELD OF THE INVENTION AND RELATED ART

This invention relates to a plasma processing apparatus for performing a process such as etching of a thin film or ashing, for example, to a surface of a workpiece substrate to be processed, such as a silicon wafer or a glass substrate placed in a reaction room, for example.

Semiconductor device manufacturing processes include an etching process for selectively etching an oxide film formed on the surface of a semiconductor wafer (hereinafter simply “wafer”), and a process for locally injecting impurities (ions) such as phosphorus, arsenic, boron, etc. into the wafer surface. In these processes, in order to prevent etching of or ion injection into an undesired portion, a pattern of a resist film consisting of an organic substance such as photosensitive resin is formed on the topmost surface of the wafer, by which the undesired portion not to be etched or ion injected can be masked by the resist film. Since the resist film formed in a pattern upon the wafer becomes unnecessary after the etching or ion injection process. Therefore, after the etching or ion injection, a resist removing process for removing the unnecessary resist film on the wafer is carried out.

The resist removing process can be accomplished, for example, by ashing the resist film by use of an ashing machine and, after that, the wafer is moved into a washing machine to remove the resist material remaining after the ashing, from the wafer surface. In such ashing machine, as an example, a processing chamber accommodating therein a wafer to be processed is filled with an oxygen gas ambience, and microwaves are projected into the oxygen gas ambience. In response, plasma of oxygen gas (i.e. oxygen plasma) is produced within the processing chamber, and the wafer surface is exposed to this plasma by which the resist on the wafer surface is decomposed and removed.

Where a conventional down-flow type resist removing machine is used, a few problems are raised.

One problem is that it becomes very difficult to remove a resist having been altered and stiffened by ion injection. This is because the resist is carbonized by heat upon ion injection and due to O₂ radicals it is oxidized into CO, CO₂, H₂O, etc. Thus, the resist can not be vaporized easily and, therefore, the time required for resist removal is prolonged. Also, because the vapor pressure of oxide of injection species (e.g., P+, As+ and B+) is low, it is easily left there. Anyway, as a result, with use of oxygen gas plasma, the resist film can not be removed completely or a long time is required to remove the same.

It is known that a resist film having its surface altered by ion injection can be removed by using, as a processing gas, a mixed gas made by adding a carbon fluoride series gas as represented by CF₄ into an oxygen gas, and on the basis of active series of fluorine as produced when plasma of this processing gas is excited.

However, if plasma that contains active series of fluorine, for example, is continuously projected to a dielectric material (microwave introducing window material) for a long time, the surface of the microwave introducing window material may be corroded, and the reactant produced by corrosion may fall upon a wafer as particles.

There is another method that a corrosive gas such as sulfur hexafluoride or carbon tetrafluoride, for example, is introduced into a reactor separately from a plasma producing gas. One method for introducing these gases into a reactor separately may be that a plasma producing gas is introduced into a plasma processing container from adjacent a dielectric material window, spaced from a wafer, and on the other hand a reaction gas is introduced while a partition plate having bores for passing the plasma gas therethrough and a discharging port for the processing gas is disposed at a position away from the dielectric material window. Another method may be that, at a position different from a plasma producing gas introduction port, a reaction gas is introduced through a wall surface of a plasma processing container to excite the plasma gas.

Another problem raised in relation to plasma processing based on microwaves is that ions which are charged particles produced by plasma production may damage a wafer which is an object to be processed.

An example is as follows. Where a plasma producing gas is turned into plasma state and into active species, by means of microwaves introduced through a microwave transmitting window, in order that a photoresist film formed in a predetermined pattern on a semiconductor substrate is removed by use of plasma produced from the plasma producing gas, a gas containing oxygen is used as a reaction gas. The plasma of the oxygen containing gas contains oxygen radicals (O*) and oxygen ions (O++). While the radicals of active species act on the object to be processed to cause ashing or etching of the same, the ions as incident may induce radiation damage of or under a gate oxide film. In order to avoid this, by some means, ions must be prevented from entering a wafer processing chamber. A partition plate may be disposed to this end, to release ions and to thereby prevent entering of ions.

However, where a down-flow type plasma ashing machine is used and if a blocking member as represented by a partition wall described above is disposed between a plasma producing portion and a wafer (object to be processed) although the purpose and effect are different as described hereinbefore, it would provide a large resistance to a gas flow flowing through the processing container. As a result, a pressure gradient would be produced across the blocking member and, in the case of partition plate described above, between a gas introducing portion which is at the plasma producing chamber side and a wafer processing chamber side which is at the wafer side to be processed.

If such pressure gradient is actually produced between the plasma producing chamber and the wafer processing chamber, a pressure rise occurs at the plasma producing chamber side which is a plasma producing portion, and in turn it causes shortening of the mean free path of plasma particles. In other words, the collision frequency of plasma particles becomes large, and this may cause deactivation of the plasma particles.

If the pressure inside the plasma producing chamber rises and, as a result, the plasma is deactivated and the plasma density is lowered, it adversely affects the wafer processing and the processing speed.

Examples of possible adverse effect are a decrease of processing speed due to deactivation, degradation of processing uniformess, and failure of processing depending on the film property or type of the film.

Furthermore, where the plasma producing gas portion and the processing gas introducing portion are separated from each other, due to deactivation of the plasma gas the excitation of processing gas is weakened. This may cause similar problems such as a decrease of processing speed, degradation of processing uniformess, and failure of processing depending on the film property or type of the film.

### SUMMARY OF THE INVENTION

It is accordingly an object of the present invention to provide an improved plasma processing system by which at least one of the inconveniences described above can be removed or reduced.

It is another object of the present invention to provide a microwave plasma processing machine having a partition wall, by which pressure gradient at zones divided by the partition wall can be diminished to reduce deactivation at a plasma producing portion.

It is a further object of the present invention to provide a structure in which the size or angle of an opening (bore) of a partition wall and of rectifying plates having different tilt angles can be adjusted to prevent incidence of microwaves upon a wafer (object to be processed) thereby to reduce damage of the same, the position of the opening being adjustable to suppress reaction, to a microwave introducing window material, of a corrosive gas such as sulfur hexafluoride, carbon tetrafluoride, nitrogen trifluoride, etc. which may cause corrosion of the microwave introducing window material.

In accordance with an aspect of the present invention, to achieve at least one of these objects, there is provided a plasma processing apparatus, comprising: a plasma producing chamber into which a microwave and a plasma producing gas are to be introduced; a processing chamber being able to be communicated with said plasma producing chamber; a workpiece table provided inside said processing chamber, for carrying thereon a workpiece to be processed; and a partition plate provided at an interface between said plasma producing chamber and said processing chamber, and having openings for connecting said plasma producing chamber and said processing chamber for communication therebetween, wherein said partition plate includes rectifying plates being provided at said openings with predetermined different tilt angles, and a reaction gas discharging port for discharging a reaction gas into said processing chamber. A microwave producing portion and a gas supplying portion for supplying the plasma producing gas may be provided at a plane parallel to the workpiece table or a sectional plane of the openings. The reaction gas discharging port may preferably be provided at a plane parallel to the workpiece table or a sectional plane of the openings.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1A is a schematic and plane view of a main portion of a microwave plasma processing machine according to a first embodiment of the present invention.

FIG. 1B is a sectional view of the main portion of the microwave plasma processing machine of FIG. 1A.

FIG. 2 is a schematic view, showing results of simulations made with respect to a model having rectifying plates according to an embodiment of the present invention.

FIG. 3 is a schematic view, showing results of simulations made with respect to a model without having rectifying plates according to the present invention.

FIG. 4 is a schematic and sectional view for explaining a microwave plasma processing machine according to a second embodiment of the present invention.

### DESCRIPTION OF THE PREFERRED EMBODIMENTS

Preferred embodiments of the present invention will now be described with reference to the attached drawings. Specifically, while taking a down-flow type plasma processing machine as an example, preferred embodiments of the present invention as well as the results of simulations will be explained in detail.

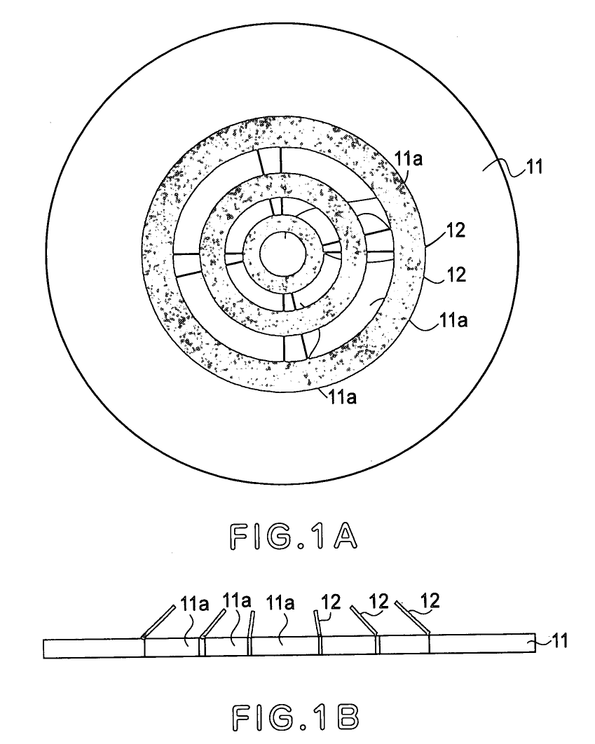

One preferred embodiment of the present invention has features that, inside a plasma processing container of a plasma processing machine, a partition wall for dividing zones is provided between a plasma producing chamber and a wafer processing chamber, that the partition wall is provided with openings (holes) such as shown in FIGS. 1A and 1B, as an example, and that at the plasma producing chamber side the openings (holes) are provided with rectifying plates having different angles.

Namely, a plasma processing apparatus according to one preferred form of the present invention comprises a plasma producing chamber in which a reaction gas is to be tuned into plasma by microwaves, a wafer processing chamber for processing a surface of a semiconductor wafer by use of the plasma produced in the plasma producing chamber, and a partition plate for separating the plasma producing chamber and the wafer processing chamber from each other and having openings (holes) formed therein, wherein the partition plate includes rectifying plates provided at the plasma producing chamber side with different angles, which rectifying plates serve to rectify the plasma from the plasma processing chamber to thereby reduce any pressure gradient of the plasma producing chamber and the wafer processing chamber and to thereby reduce deactivation inside the plasma producing chamber.

A plasma processing apparatus according to another preferred form of the present invention comprises a plasma producing chamber in which a reaction gas is to be tuned into plasma by microwaves, a wafer processing chamber for processing a surface of a semiconductor wafer by use of the plasma produced in the plasma producing chamber, and a partition plate for separating the plasma producing chamber and the wafer processing chamber from each other, wherein the partition plate serves to prevent ion components, produced when the plasma producing gas is turned into plasma, form entering the wafer processing chamber or reduce the entry of ion components into the wafer processing chamber, and it serves to introduce, into the wafer processing chamber, radicals which are produced when the plasma producing gas is turned into plasma. A heater for heating the semiconductor wafer may be provided in the wafer processing chamber.

The area of the openings (holes) of the partition plate as well as the angle and size of the rectifying plates may be adjusted to prevent damage of the wafer (object to be processed) which might be caused by direct irradiation of the wafer with microwaves entering the plasma producing chamber through a microwave introducing window.

In order to reduce damage of the partition plate by microwaves entering the plasma producing chamber through the microwave introducing window, the partition plate may preferably be disposed at a distance of Nxλ/2 from the surface of the microwave introducing window, where N is an integer and λ is the wavelength of the microwaves used for the plasma production.

The shape and area of the openings of the partition plate may be adjusted and, where a corrosive gas such as sulfur hexafluoride, carbon tetrafluoride, nitrogen trifluoride, etc. is used, this may advantageously reduce production of a reaction substance due to the reaction of the corrosive gas and the microwave introducing window material and, furthermore, it may prevent deposition of a substance produced by reaction of the wafer (object to be processed) and its constituent substance onto the wall surface of the plasma processing container. Thus, in that occasion, creation of particles due to peeling-off of the deposited substance can be reduced effectively.

### Embodiment 1

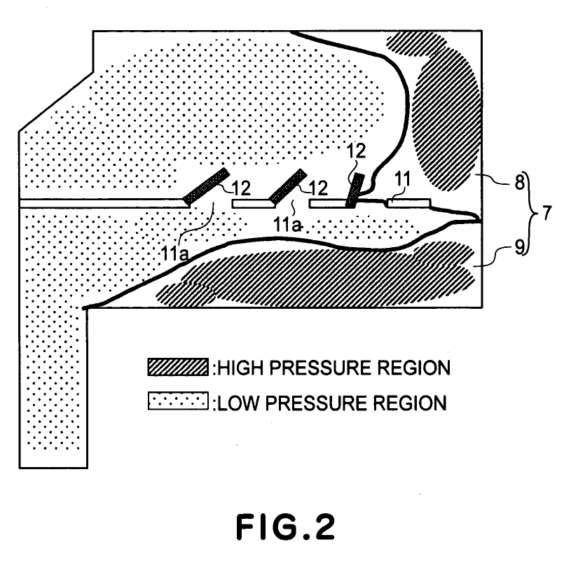

FIG. 1A is a schematic and plan view of a microwave processing apparatus according to a first embodiment of the present invention. FIG. 1B is a sectional view of the same. First, in order to investigate the pressure gradient reducing effect of the rectifying plates provided on the partition plate of the present invention, a fluid analysis software STAR-LT was used and simulations were made in regard to a model prepared under the conditions described below. FIG. 2 illustrates the results of simulations of the model having rectifying plates according to the first embodiment of the present invention.

The partition plate denoted at 11 has such structure that radial openings (holes) 11a are formed at positions ranging from the central axis of the plasma processing container to a half of the distance from the central axis to the side wall of the plasma processing container 7, the openings being shaped with a lattice so that the rectifying plates denoted at 12 can be provided on the way of this range. Three rectifying plates 12 were disposed concentrically upon the partition plate 11 and at the plasma producing chamber 8 side thereof. These rectifying plates 12 were provided at different angles of 80 deg., 60 deg. and 45 deg., respectively, with respect to a wafer carrying table (or the partition plate parallel to it), in an order from the central axis to the side wall of the plasma processing container 7.

Regarding the gas flow rate, the calculations were made under the conditions that an oxygen gas as a plasma producing gas was supplied into a plasma producing zone at 2500 sccm at a static pressure of 133.3 Pa, and sulfur hexafluoride (SF₆) which was a fluorine containing gas was supplied as a reaction gas through a reaction gas nozzle, provided on the surface of the partition plate 11 being parallel to the wafer carrying table, at a total supply rate 10 sccm.

Furthermore, in order to make it clear the advantageous effect of the present invention, calculations were made in regard to a model having rectifying plates 12 at the plasma producing chamber 8 side of the partition plate 11 according to the present invention as well as a model having no such rectifying plates. Except this, the calculations were made under the same model condition and also under the same conditions in regard to gas flow rate, pressure, number of calculation times, and so on.

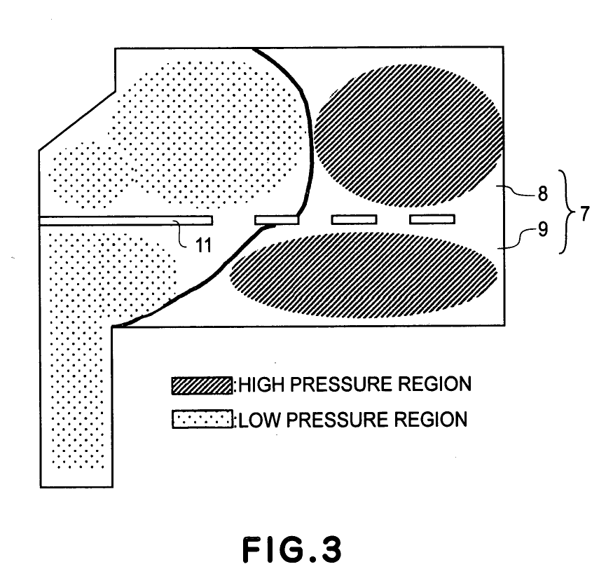

As a result, it was confirmed that, in the model having rectifying plates 12 as shown in FIG. 2, as compared with the model without rectifying plates shown in FIG. 3, the pressure gradient between the plasma producing chamber 8 and the processing chamber 9 having a wafer carrying table therein, at the opposite sides of the partition plate 11, was significantly reduced.

### Embodiment 2

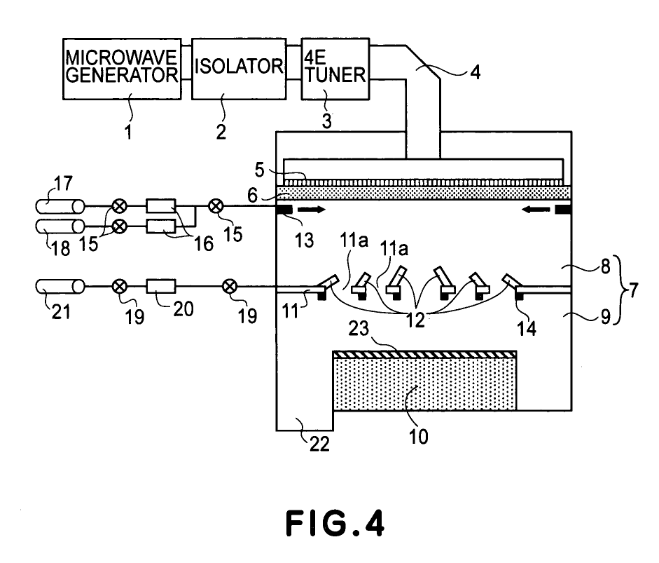

FIG. 4 is a schematic and sectional view of a microwave plasma processing apparatus according to a second embodiment of the present invention. In the down-flow type microwave plasma processing machine of FIG. 4, microwaves of 2.45 GHz, for example, produced by a microwave generator 1 are directed through a microwave guide tube 4 to a slot antenna 5. The microwave guide tube 4 is connected so that the direction of microwaves advancing above the plasma processing container 7 becomes in parallel to a microwave introducing window 6 and the slot antenna 5. An isolator 2 and a 4E tuner 3 are connected to another end of the microwave guide tube 4. The microwaves directed to the slot antenna 5 are introduced into the plasma producing zone inside the plasma processing container 7 through the microwave introducing window 6 which is made of a dielectric material such as, for example, quartz glass, alumina, or aluminum nitride.

Disposed inside the plasma processing container 7 is a wafer carrying table 10 for carrying thereon a wafer 23 (object to be processed) and being movable upwardly/downwardly. The wafer carrying table 10 has a heater integrated therein.

Also provided inside the plasma processing container 7 is a partition plate 11 according to the present invention, for separating a plasma producing chamber 8 and a wafer processing chamber 9. The partition plate 11 has such structure that radial openings (holes) 11a are formed at positions ranging from the central axis of the plasma processing container 7 to a half of the distance from the central axis to the side wall of the plasma processing container 7. Also, at the plasma producing chamber 8 side, there are rectifying plates 12 provided on the partition plate 11 at different angles of 80 deg., 50 deg. and 20 deg., respectively, with respect to the surface of the wafer carrying table 10, in an order from the central axis to the side wall of the plasma processing container 7. The partition plate 11 is disposed inside the plasma processing chamber positioned between the microwave introducing window 6 and the wafer carrying table 10 (stage). It functions to separate and define the inside space of the plasma processing container 7 at the microwave introducing window side as a zone for the plasma producing chamber 8, and the inside space of the plasma processing container 7 at the wafer carrying table 10 side as a zone for the wafer processing chamber 9.

A plasma gas introducing port comprises plasma gas producing gas nozzles 13 having a plurality of discharging ports and being provided at the plasma producing chamber 8 side of the plasma processing container 7. A reaction gas (fluorine containing gas) discharging port comprises reaction gas nozzles 14 provided by a large number of small bores (ø is about 0.5-1 mm) formed at the wafer processing chamber 9 side in a plane parallel to the wafer carrying table 10 and the sectional plane of the partition plate 11. As regards the direction of gas discharging from the reaction gas nozzles 14, it may be chosen arbitrarily in accordance with the specific flow rates of the plasma producing gas and the reaction gas as well as the inside pressure of the processing chamber.

The plasma gas nozzle 13 is connected to a gas introducing device that comprises valves 15 and mass flow controllers 16, etc. To this gas introducing device, an oxygen containing gas can supplied from an oxygen containing gas source 17 and, on the other hand, a rare gas or a nitrogen gas can be supplied from a rare gas source 18 or a nitrogen gas source. By controlling the opening/closing of the valves 15 of respective gas supplying lines (oxygen gas supply line and nitrogen gas supply line) and by controlling the mass flow controllers 16, the kind of a gas to be introduced into the plasma producing chamber through the plasma producing nozzle 13 can be changed. Furthermore, by controlling the mass flow controllers 16 provided on the gas supply lines, the flow rate of the plasma producing gas to be supplied into the plasma producing chamber through the nozzle 13 as well as the concentration of contained gas components (gas mixture ratio) can be changed as desired. On the other hand, a reaction gas (fluorine containing gas) introducing tube for supplying a reaction gat to the reaction gas nozzles 14 provided on the partition plate 11 is connected to a gas introducing device that comprises valves 19 and a mass flow controller 20, etc, such that the supply amount of the reaction gas from a fluorine containing gas source 21 can be changed.

A gas exhaust port 22 is provided adjacent the wafer carrying table 10 at the wafer processing chamber 9 side, placed at the bottom of the plasma processing chamber 7. An unshown exhaust system is connected to this exhaust port, to exhaust the gas so that the pressure inside the plasma processing container 7 is adjusted and maintained at a pressure not higher than the atmospheric pressure and not less than 13.3 Pa.

In operation of the plasma reaction device of the structure described above, the pressure condition is adjusted at 106.6 Pa, and, as plasma producing gas, oxygen and argon are supplied and mixed each being at a flow rate of 800 sccm. After the plasma producing chamber 8 is filled with the plasma producing gas, the microwave oscillator 1 produces microwaves at an electric power of 3 kW, and the microwaves are projected into the plasma producing chamber 8 through the microwave introducing window 6. By means of the energy of the radiated microwaves, the mixed gas inside the plasma producing chamber 8 is excited into high density plasma.

Then, oxygen active species and argon active species produced by the high density plasma are supplied into the wafer processing chamber 9 by means of the rectifying plate 12 of the partition plate 11 without being deactivated by collision, such that, while effectively exciting sulfur hexafluoride (SF₆) of 10 sccm which is fluorine containing gas supplied through the reaction gas nozzles 14 of the partition plate 11, they can reach the resist pattern formed on the wafer 23 surface. Thus, the resist pattern can be ashed efficiently while suppressing the decrease of processing speed and minimizing the change in processing capacity.

As regards the oxygen containing gas as the plasma producing gas, any one of O₂, N₂O, NO₂, CO₂, etc., may be used. As regards the fluorine containing gas, any one of F₂, NF₃, SF₆, CF₄, C2F₆, C₄F₈, CHF₃, CH₂F₂, CH₃F, C₃F₈, S₂F₂, SF₂, SF₄, SOF₂, etc., may be used. As regards the diluting gas of oxygen to be used in a process forming gas, a rare gas such as He, Ne, Ar or the like, or alternatively, nitrogen, may be used.

In accordance with this embodiment of the present invention as described above, where a blocking member (as can be represented by a partition plate) that may provide a resistance to the gas flow of process gas in a plasma processing container of a down-flow type plasma processing machine, rectifying plates are provided at the plasma producing chamber side of the partition plate at different tilt angles. This effectively prevents a pressure rise at the plasma producing chamber side, and thus it reduces production of pressure gradient at the processing chamber side where a wafer or the like to be processed is mounted. Because the pressure rise in the plasma producing chamber is suppressed, deactivation of plasma particles can be reduced effectively such that undesirable results of decrease of processing speed, degradation of process uniformess, failure of process depending on the film quality or type of the film, can be prevented effectively.

If the plasma producing gas portion and the processing gas introducing portion are separated from each other as described above, deactivation of plasma gas can be reduced such that the processing gas can be excited easily. Therefore, undesirable results of decrease of processing speed, degradation of process uniformess, failure of process depending on the film quality or type of the film, can be prevented similarly.

Furthermore, by adjusting the angle and size of the rectifying plates and the openings (holes) of the partition plate, damage of a wafer or any other object to be processed, due to irradiation of the same with microwaves introduced into the plasma processing container can be avoided or reduced effectively. Also, by adjusting the openings (holes), undesirable kick-up of product materials after the reaction process as well as contact of corrosive gas to the dielectric material window can be avoided effectively.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-194234 filed Jun. 30, 2004, for which is hereby incorporated by reference.

What is claimed is:

1. A plasma processing apparatus, comprising:
a plasma producing chamber into which a microwave and a plasma producing gas are to be introduced;
a processing chamber being able to be communicated with said plasma producing chamber;
a workpiece table provided inside said processing chamber, for carrying thereon a workpiece to be processed; and
a partition plate provided at an interface between said plasma producing chamber and said processing chamber, and having openings for connecting said plasma producing chamber and said processing chamber for communication therebetween, wherein said partition plate includes rectifying plates being provided at said openings with predetermined different tilt angles, and a reaction gas discharging port for discharging a reaction gas into said processing chamber.

2. An apparatus according to claim 1, wherein said reaction gas discharging port is provided with means for adding a dilution gas chosen out of a rare gas and a nitrogen gas.

3. An apparatus according to claim 1, wherein said processing chamber is provided with a gas discharging port for rectifying an exhaust gas therefrom.

4. An apparatus according to claim 1, wherein said reaction gas discharging port is disposed at a sectional plane of the openings.

5. An apparatus according to claim 1, wherein said partition wall is made of an insulating material.

6. An apparatus according to claim 1, wherein said processing chamber has an inside ambience being kept at a pressure lower than an atmospheric pressure but not lower than 13 Pa.

7. An apparatus according to claim 1, wherein said partition plate is disposed at a position spaced from a surface of a dielectric material member, for introducing the plasma producing gas, by a distance being equal to a length defined by multiplying a wavelength of the microwave by n/2, where n is an integer.

8. An apparatus according to claim 1, wherein said reaction gad discharging port discharges, as a corrosive gas, a gas having a molecular structure containing at least one halogen atom.
